(19) United States
(12) Patent Application Publication
(10) Pub. No.: US 2025/0123310 A1
(43) Pub. Date: Apr. 17, 2025

(54) OIL LEVEL MONITORING SYSTEM

(71) Applicant: FORD GLOBAL TECHNOLOGIES, LLC, Dearborn, MI (US)

(72) Inventors: Yijing Zhang, Danville, CA (US); Ankit Saini, Novi, MI (US); Benjamin J. Graves, West Bloomfield, MI (US); Hossein Gholizadeh, La Grange, IL (US); Deepthi Antony, Farmington Hills, MI (US); Zhengyu Dai, Canton, MI (US); Steven Anatole Frait, Milan, MI (US)

(21) Appl. No.: 18/484,876

(22) Filed: Oct. 11, 2023

(51) Int. Cl. G01R 21/06; G05B 13/02; G06N 5/022

(52) U.S. Cl. CPC G01R 21/06; G05B 13/027; G06N 5/022

(57) ABSTRACT

A method of monitoring a fluid level in a power unit relies on a neural network model. The model is used to predict lateral acceleration during air ingestion events. These predictions are compared to measured values of lateral acceleration. When the measured values and the predicted values are not well correlated, a controller takes corrective action.

### TECHNICAL FIELD

The present disclosure relates to a method of monitoring fluid level in a vehicular power unit. More particularly, the disclosure relates to a method based on machine learning.

### BACKGROUND

In a power unit of a vehicle, fluid is actively circulated to provide cooling and lubrication. The fluid is circulated, using an electric pump, from a sump to various outlets located strategically throughout the power unit. In some circumstances, lateral acceleration may move the fluid in the sump such that a fluid inlet is exposed to air instead of fluid. This is more common if the fluid level decreases due to leakage. Directly measuring the fluid level requires additional parts which may have imperfect reliability.

### SUMMARY

A vehicle includes a power unit, an electric pump, and a controller. The power unit has a sump containing fluid. The power unit may be an electric drive unit comprising a motor and a gearbox. The electric pump is configured to pump the fluid from an inlet in the sump to a plurality of outlets. The controller is programmed to detect a change in a fluid level and respond accordingly. The controller measures lateral acceleration. The controller also predicts lateral acceleration, using a model, based on power consumption of the electric pump. The controller may considers lateral acceleration in only one direction. The model may be a neural network model which has been trained using experimental data obtained using a predetermined quantity of fluid. The model may also use a measure vehicle speed. In response to a correlation metric between the measured lateral acceleration and the predicted lateral acceleration being less than a threshold, the controller restricts flow to a subset of the plurality of outlets to ensure that flow is maintained to higher priority outlets. The controller may also issue a signal to an operator.

A power unit for a vehicle includes a housing, an electric pump, and a controller. The housing defines a sump containing fluid. The electric pump is configured to pump the fluid from an inlet in the sump to a plurality of outlets. The controller is programmed to detect a change in a fluid level and respond accordingly. The controller measures lateral acceleration, vehicle speed, and a power consumption of the electric pump. The controller then predicts lateral acceleration using a model based on the power consumption and the vehicle speed. The controller may considers lateral acceleration in only one direction. The model may be a neural network model trained using experimental data obtained using a predetermined quantity of fluid. In response to a correlation metric between the measured lateral acceleration and the predicted lateral acceleration being less than a threshold, the controller restrict flow to a subset of the plurality of outlets to ensure that flow is maintained to higher priority outlets. The controller may also issue a signal to an operator. The power may also include a traction motor and a gearbox.

A method of detecting an abnormal fluid level includes comparing a predicted lateral acceleration to a measured lateral acceleration. Fluid is pumped from a sump to a plurality of outlets using an electric pump. A power consumption of the electric pump and a lateral acceleration are measured. An air ingestion event is identified based on a change in the power consumption. During the air ingestion event, a predicted lateral acceleration is computed using a model based on the measured power consumption. The model may be a neural network model. The model may also use a measured vehicle speed. In response to a correlation metric between the measured lateral acceleration and the predicted lateral acceleration being less than a threshold, flow is restricted to a subset of the plurality of outlets to ensure that flow is maintained to higher priority outlets. A signal may also be issued to an operator. The method may include training the model using experimental data obtained using a predetermined quantity of fluid in the sump. The method may consider lateral acceleration in only one direction.

### BRIEF DESCRIPTION OF THE DRAWINGS

FIG. 1 illustrates a block diagram of a hybrid electric vehicle.

FIG. 2 is a side cross section of a power unit suitable for use in the vehicle of FIG. 1.

FIGS. 3A, 3B, and 3C are end views of the power unit of FIG. 2 in various conditions.

FIG. 4 is a graph of several parameters during an air ingestion event in the power unit of FIG. 2.

FIG. 5 is a flow chart for building a model to predict lateral acceleration in the vehicle of FIG. 1.

FIG. 6 is a flow chart for a method to monitor fluid level in the vehicle of FIG. 1 using the model built using FIG. 5 and responding to loss of fluid.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

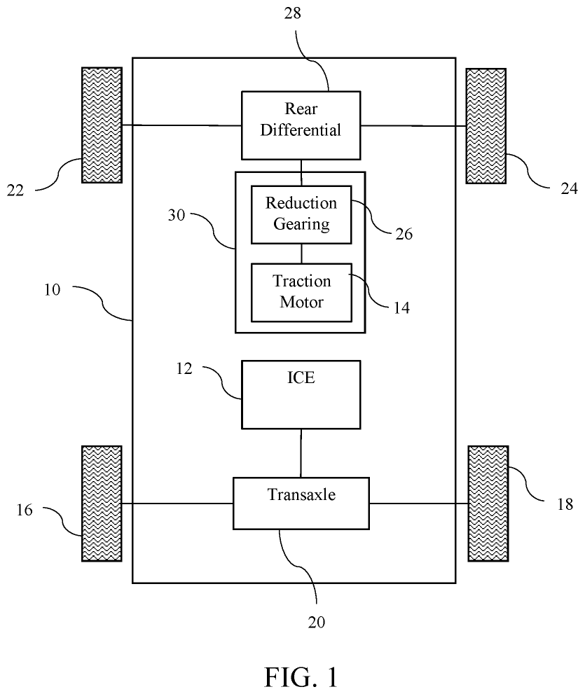

FIG. 1 illustrates a vehicle powertrain configuration for a hybrid vehicle 10. Power is provided by an internal combustion engine 12 and by an electric traction motor 14. At a given time, power may be provided by the engine 12, by traction motor 14, or by a combination of the two. The engine 12 drive front wheels 16 and 18 via a transaxle 20. The traction motor 14 drives rear wheels 22 and 24 via speed reduction gearing 26 and rear differential 28. The traction motor 14 and the reduction gearing may be housed in a common housing 30 and referred to collectively as a power unit. The power unit may also include the differential. The combination of the internal combustion engine and the transaxle may also be referred to as a power unit. A vehicle may have only a single power unit or may have multiple power units of the same type.

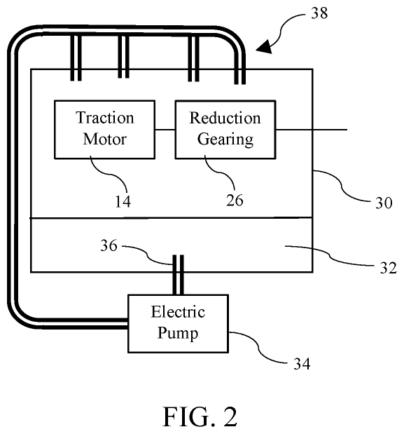

FIG. 2 is a side view of the power unit. Housing 30 defines a sump which contain a fluid 32. An electric pump 34 circulates the fluid by drawing the fluid from an inlet 36 in the sump and distributing the fluid to a set of outlets 38. The outlets are placed such that the fluid provides cooling and lubrication to components of the traction motor 14 and the reduction gearing 26. The fluid then drains back into the sump due to gravity.

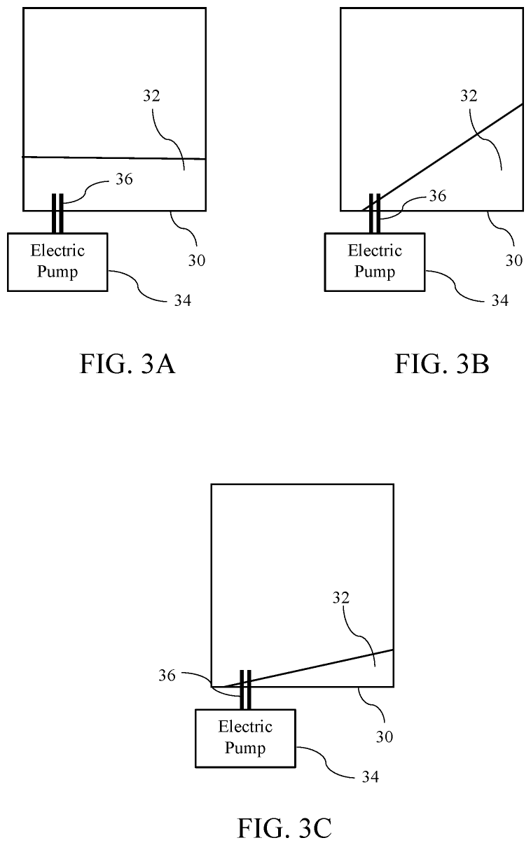

FIG. 3A is an end view of the power unit with the fluid filled at a nominal level and power unit not subject to any lateral acceleration. Notice that the inlet 36 is not necessarily centered. FIG. 3B illustrates a situation in which the power unit is subject to a lateral acceleration to the right. The lateral acceleration may be due to the vehicle turning, the vehicle being driven on a slanted roadway, or some combination of the two. In this situation, air may be ingested into inlet 36. Due to the offset location of inlet 36, a lateral acceleration to the left would not cause air ingestion. When the fluid quantity is at the nominal level, air ingestion events are sufficiently rare and short in duration that the brief interruptions of cooling flow or lubrication flow is not an issue. FIG. 3C illustrates a situation in which the fluid level has decreased from the nominal level. This may be due to a slow leak, for example. With the lower fluid level, air ingestion occurs at lower degrees of rightward lateral acceleration. As a result, the air ingestion events occur more frequently and tend to last longer, increasing the likelihood of an interruption of cooling or lubrication.

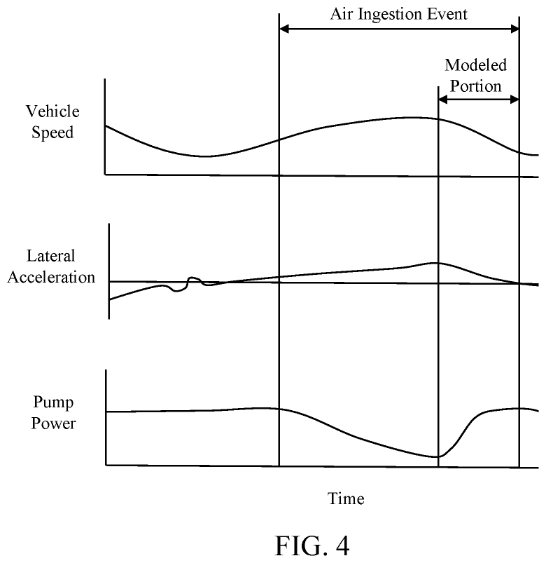

FIG. 4 graphically illustrates an air ingestion event as a function of time. The air ingestion causes the electrical power required by the electric pump to decrease due to the negligible density of the air relative to the fluid. Notice that the leftward lateral acceleration (indicated by negative values) does not cause air ingestion. When the lateral acceleration exceeds some value, the pump power begins to drop. It continues to drop as the fluid currently in the lines is pumped through the lines. Pump power returns to its normal level when lateral acceleration decreases. The inventors have discovered that vehicle speed influences the relationship between lateral acceleration and pump power.

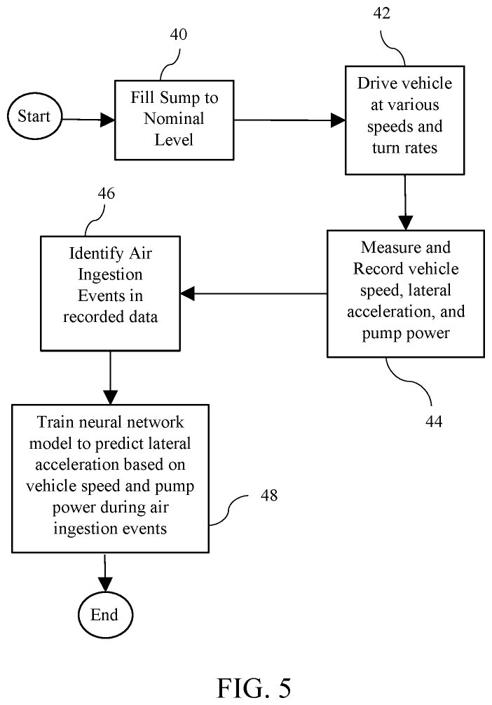

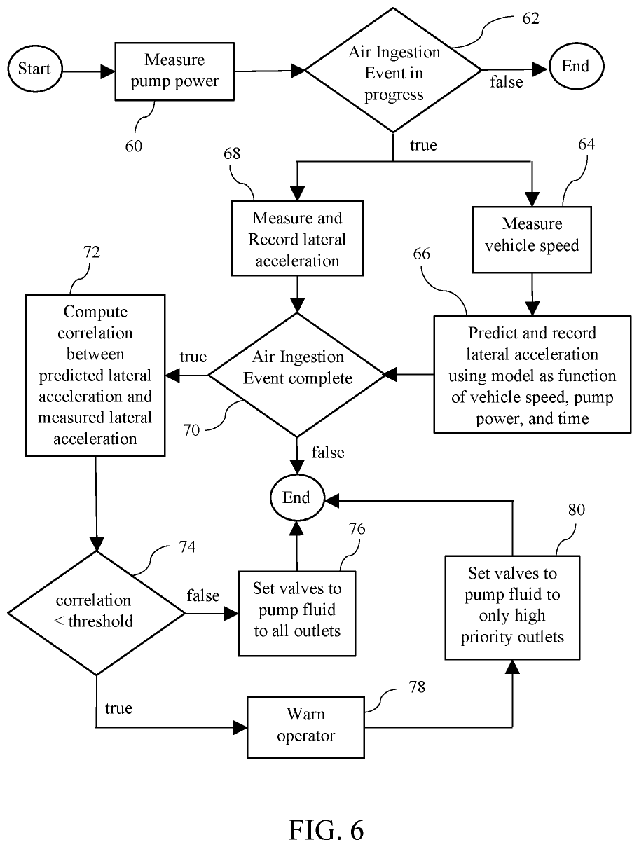

A machine learning model, such as a neural network model, may be created which predicts the lateral acceleration as a function of pump power and vehicle speed during air ingestion events. The causality of the neural network model may be reversed from the causality of the physical system. The inventors have discovered that such a neural network model, when trained using data obtained with a particular fluid level, accurately predicts the lateral acceleration. The inventors have further discovered that, when the fluid level changes enough to require corrective action, the predicted lateral acceleration does not correlate well with the observed lateral acceleration. FIGS. 5 and 6 illustrate a method based on these discoveries to monitor the fluid level in a power unit of a vehicle.

FIG. 5 is a flow chart for a method to create the neural network model. This method may be carried out when a vehicle first enters service. Alternatively, it may be carried out on a vehicle that is representative of the vehicle in which the fluid level monitoring will be performed. At 40, the sump is filled to a nominal level. At 42, the vehicle is driven through a drive cycle in which a number of air ingestion events of various degrees of severity and duration will occur. While the vehicle is being driven at 42, parameters such as vehicle speed, lateral acceleration, and pump power are measured and recorded at 44. At 46, the data is processed to identify air ingestion events and create separate records for each event. Each record indicates the vehicle speed, lateral acceleration, and pump power as a function of time measured from the beginning of the event. This processing may occur in real time while the data is being gathered or it may be performed in a post-processing step. To facilitate event identification, a subset of the air ingestion event may be utilized instead of the entire event. As illustrated in FIG. 4, the model may utilize only the portion of each event following the time that the pump power starts to increase. At 48, the neural network model, or other data-trained type of model, is trained using the data obtained at 46.

FIG. 6 is a flow chart for a process executed by a controller associated with the power unit. This process is executed at regular intervals, such as once every 100 milliseconds. At 60, the pump power is measured directly or indirectly. For example, the pump power may be measured indirectly by measuring current and voltage and multiplying the values. At 62, the process determines whether or not an air ingestion event, or a modeled portion of an air ingestion event, is ongoing. The controller may recognize a start of a new event by an increasing pump power. The controller may conclude that an even is ongoing based on detecting the start of an event at a previous time and not yet recognizing an end of that event. If no air ingestion event is in progress at 62, the process ends.

If it is determined at 62 that an air ingestion event is in progress, then the vehicle speed is measured at 64. The vehicle speed measured at 64, the pump power measured at 60, and the time since the start of the event is used at 66 to predict lateral acceleration using the model trained via the process of FIG. 5. At 68, the lateral acceleration is measured and recorded. The measured lateral acceleration may be unidirectional, meaning that only lateral acceleration to the left or to the right is considered. At 70, the controller determines whether or not the air ingestion event is complete. Completion may be determined, for example, by the pump power returning to its nominal level and lateral acceleration as measured at 68 being less than a threshold. If the air ingestion is not yet complete, the process ends.

Upon completion of the air ingestion event, the controller compares the measured lateral acceleration from 68 to the predicted lateral acceleration from 66 at each time point during the just completed event. A correlation statistic, such as R-squared, is computed at 72 to quantify the degree of agreement between the measured and the predicted values. At 74, this correlation statistic is compared to a threshold. If a high degree of agreement is indicated, the controller concludes that the fluid level is near the nominal level and sets valves at 76 such that fluid gets pumps to all of the outlets.

If, at 74, the controller finds that the measured lateral acceleration is not well correlated with the predicted lateral acceleration, then the controller concludes that the fluid level must have decreased significantly from the nominal level. In response, the controller informs the operator at 78 and adjusts the valves at 80 such that fluid is pumped only to high priority outlets. This ensures that the high priority outlets will receive sufficient flow despite occasional interruptions due to air ingestion events. Which outlets are considered high priority may depend on the operating conditions. For example, in high ambient temperatures, outlets associated with providing cooling are highest priority. In other circumstances, outlets associated with lubrication may be higher priority.

In the embodiment illustrated in FIG. 6, the controller adjusts the valves based on the single most recent air ingestion event. In alternative embodiments, the controller may wait until a pattern emerges over a series of such events, or may implement corrective actions gradually in phases.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of these disclosed materials. The terms “controller” and “controllers,” for example, can be used interchangeably herein as the functionality of a controller can be distributed across several controllers/modules, which may all communicate via standard techniques.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle comprising:
a power unit having a sump containing fluid;
an electric pump configured to pump the fluid from an inlet in the sump to a plurality of outlets; and
a controller programmed to
measure lateral acceleration,
predict, using a model, lateral acceleration based on power consumption of the electric pump, and
in response to a correlation metric between the measured lateral acceleration and the predicted lateral acceleration being less than a threshold, restrict flow to a subset of the plurality of outlets.

2. The vehicle of claim 1 wherein the power unit is an electric drive unit comprising a motor and a gearbox.

3. The vehicle of claim 1 wherein the model is a neural network model.

4. The vehicle of claim 3 wherein the model has been trained using experimental data associated with a sump containing a predetermined quantity of fluid.

5. The vehicle of claim 1 wherein the measured lateral acceleration is unidirectional.

6. The vehicle of claim 1 wherein the controller is further configured to measure vehicle speed and wherein the model is further based on vehicle speed.

7. The vehicle of claim 1 wherein the controller is further configured to, in response to the correlation metric being less than the threshold, issue a signal to an operator.

8. A power unit for a vehicle comprising:
a controller programmed to, in response to a correlation metric between a measured lateral acceleration and a predicted lateral acceleration, that is generated via a model using power consumption of an electric pump configured to pump fluid from an inlet to a plurality of outlets, being less than a threshold, restrict flow to a subset of the plurality of outlets.

9. The power unit of claim 8 further comprising:
a traction motor; and
a gearbox.

10. The power unit of claim 8 wherein the model is a neural network model.

11. The power unit of claim 10 wherein the model has been trained using experimental data obtained using a predetermined quantity of fluid.

12. The power unit of claim 8 wherein the measured lateral acceleration is unidirectional.

13. The power unit of claim 8 wherein the controller is further configured to, in response to the correlation metric being less than the threshold, issue a signal to an operator.

14. A method of detecting an abnormal fluid level, the method comprising:
pumping fluid from a sump to a plurality of outlets using an electric pump;
measuring a power consumption of the electric pump and a lateral acceleration;
identifying a beginning of an air ingestion event based on a change in the power consumption;
during the air ingestion event, computing a predicted lateral acceleration using a model based on the measured power consumption;
comparing the predicted lateral acceleration during the event to the measured lateral acceleration during the event; and
in response to a correlation metric between the measured lateral acceleration and the predicted lateral acceleration being less than a threshold, restricting flow to a subset of the plurality of outlets.

15. The method of claim 14 wherein the model is a neural network model.

16. The method of claim 15 further comprising training the model using experimental data obtained using a predetermined quantity of fluid in the sump.

17. The method of claim 14 wherein the measured lateral acceleration is unidirectional.

18. The method of claim 14 further comprising measuring vehicle speed and wherein the model is further based on the measured vehicle speed.

19. The method of claim 14 further comprising, in response to the correlation metric being less than the threshold, issuing a signal to an operator.
